(19) United States
(12) Patent Application Publication
(10) Pub. No.: US 2009/0289212 A1
(43) Pub. Date: Nov. 26, 2009

(54) PROCESS FOR PRODUCING POROUS FILMS AND FILM MATERIAL PRODUCED THEREFROM

(75) Inventor: Joern Schroeer, Herdecke (DE)

Correspondence Address: ROBERTS MLOTKOWSKI SAFRAN & COLE, P.C.;Intellectual Property Department, P.O. Box 10064, MCLEAN, VA, 22102-8064, US

(73) Assignee: EWALD DOERKEN AG, Herdecke (DE)

(21) Appl. No.: 12/519,306

(22) PCT Filed: Dec. 11, 2007
(86) PCT No.: PCT/EP07/10783

§ 371 Date: Jun. 15, 2009

(30) Foreign Application Priority Data
Dec. 15, 2006 (DE) 10 2006 059 860.1

(51) Int. Cl. H01L 41/18; B29C 67/20; C08J 9/00; H01F 1/42; H01B 1/12; F21V 9/04

(52) U.S. Cl. 252/62.9 R; 264/41; 264/415; 521/50; 252/62.51 R; 252/500; 252/587

(57) ABSTRACT

A process for producing porous films (2), with the film (2) having a polymer matrix (M) and discrete domains (D) being provided in the matrix (M). According to the invention, it is proposed that the film (2) be subjected to a field for selective excitation of the domains (D), that the domains (D) be heated selectively relative to the remainer of the matrix by the excitation and that the pores (12) be produced in the domains (D) or in the region of the domains (D).

### BACKGROUND OF THE INVENTION

1. Field of Invention

The invention relates to a process for producing porous films, the film having a matrix made of plastic, in the matrix there being essentially discrete domains. Furthermore, the invention relates to a porous plastic material that is produced according to the aforementioned process as such and in its possible applications.

2. Description of Related Art

Production of porous films is known is such as by being produced, for example by sheeting material being mechanically perforated with hot or cold needles. Another type of production is by so-called open-cell foaming.

Those films that have a certain water-tightness but are permeable to water vapor are one special case of porous films. These films are conventionally referred to as breathing membranes. These films require relatively small pores and are conventionally referred to as microporous. Production of these films can take place by

open-celled foaming of dispersions

stretching of films highly filled with solids

controlled dissolving-out of certain mixture components.

Such films can be used in the most varied areas, for example:

in construction, especially for roof and facade structures,

in clothing, especially textiles, protective clothing and shoes,

in battery separators,

as membranes in fuel cells,

in or as packaging,

in the hygiene industry, especially for diapers, and

in medical technology and especially in the area of medical clothing.

In certain applications, such as, for example, in gas filtration or else in fuel cells, breathing membranes are likewise used, very fine pores being necessary, however.

In the known processes, controlling of the pore size and the number of pores in the membrane in a dedicated manner and at the same time providing an economical process for producing such films are problematic.

### SUMMARY OF THE INVENTION

The object of this invention is to avoid the disadvantages of the prior art.

To achieve the aforementioned object, it is provided according to the process that a heterogeneous active ingredient with discrete domains is used as the parent material for the film so that there are domains in the matrix, so that the film is exposed altogether to a field for selective excitation of domains, so that the domains are selectively heated by excitation, and so that the pores are produced in domains or in the region of the domains. According to the device, in the plastic material according to the invention, it is provided that in the matrix, there are essentially discrete domains so that a heterogeneous sheeting material is formed, so that the domains have been selectively excited in a field so that the domains have been heated at least in regions and/or the regions adjacent to the domains have been heated, and so that there are pores in the domains or in the region of the domains. In the invention, it is also such that the excitation of domains takes place selectively compared to the matrix or relative to the remainder of the matrix. This means that when the film is exposed in a common excitation field, the domains are heated more dramatically than the remaining matrix. This results, in turn, in that the matrix or the residual matrix is decoupled from the domains in terms of application technology, and in this way the properties of the film can be very easily controlled.

It is pointed out that domains are defined as both certain selective three-dimensional regions in the film or the matrix, as well as certain particles, fillers, pore formers or the like. Furthermore, it is noted that production of pores in the region of domains means mainly that the pores directly adjoin the domains and are adjacent to them. Preferably, the pores are formed on the boundary surfaces of the domains that will be considered in more detail below. In any case, this invention makes it possible to control both the pore size and also the number of pores in a dedicated manner in the production of the film by the choice of the corresponding domains. Thus, both comparatively large pores and also very fine pores that are necessary for certain applications can be formed.

Moreover, this invention also offers the possibility of exposing a porous film material that has been produced according to the process according to the invention to an excitation field again so that the domains, and thus, the pores are influenced again. Thus, fundamentally, it is even possible to close the original pores again afterwards following the corresponding excitation of the domains by the domains being excited so strongly and being heated in such a way that the film material melts and the originally produced pores are closed again. The invention thus ultimately makes available a process in which the pores of a porous plastic material are closed again afterwards. In another variant, the pores can be enlarged subsequently at least once by, for example, at least one further excitation taking place with simultaneous stretching.

Moreover, it goes without saying that the principle according to the invention also relates to embodiments in which the matrix in which the domains are located is selectively excited, i.e., separately and also differently than the remainder of the film. In this case, the matrix, without the domains, is selectively heated by excitation, the pores being produced in the matrix or in the region of the transition from the matrix to the domains. Therefore, such is an embodiment that is complementary to the aforementioned embodiment and that is possible not only according to the process, but also relates to the film material as such. It is expressly pointed out that the following text that relates to the embodiment of selective excitation of domains applies in the same way to selective excitation of the matrix even if this is not considered in more detail in particular.

So that the films that have been preferably produced according to the process of the invention have a porosity that is at least essentially homogenous or uniform over the surface, the domains are distributed uniformly in the film or matrix. In addition, it can also be provided that the domains are unevenly distributed. Then, films with defined regions of different porosity can be produced therefrom.

In order to be able to easily produce pores after selective heating of domains, in one preferred embodiment of the invention, it is provided that the film material is elongated or stretched during or after excitation and the resulting heating of domains. Elongation or stretching can take place monoaxially or biaxially, depending on the application. Since the film in the region of the domains has been more strongly heated than in the remaining regions, stretching leads to tearing open of the film material or the matrix in the region of the domains so that pores form that arise on the boundary surfaces of the domains or extend through the domains.

In another embodiment that can be used as an alternative to stretching or also in conjunction with stretching, in or on the domains, there is a pore-filming material (pore former) that can preferably be an essentially decomposing propellant or a coating that essentially vaporizes during excitation.

When using the propellant, after excitation in the region of the domains, a type of gas bubble is formed; this can already lead to pore formation for correspondingly large domains. In the coatings that essentially vaporize by excitation, on the domains an outer boundary layer forms that for correspondingly large domains can likewise lead to pore formation.

It is especially advantageous when the porosity, on the one hand, is produced by the use of propellants/coatings, and on the other hand, by the additional stretching. In this case, the porosity can be set in a very wide framework. Ultimately, the size and/or the number of pores in the film material is/are influenced by many factors. Here, among others, the following factors by themselves or in any combination with one another play a part:

type of domains,

number of domains,

temperature of the film material,

instant of excitation within the production process,

type of matrix material,

duration of excitation,

intensity of excitation,

degree and type of stretching,

type of propellant/coating,

amount of propellant/coating.

It is pointed out that the aforementioned list is not exhaustive.

For propellants/coatings, their ignition temperature that must be matched to the film material or matrix in which the domains are embedded is important. In contrast to conventional processing of propellant-containing plastics into foamed films, the ignition temperature can be chosen in a wider temperature range, especially to be higher, since the required temperature can be produced selectively and in a dedicated manner. Properties of interest in this respect are the gas yield and the solubility of the propellant/coating in the matrix. Preferred propellants/coatings whose approximate ignition temperature is given below in parentheses are:

azo compounds, such as, for example, azodicarbonamides (210° C.), azoisobutylonitrile,

tetrazoles, such as, for example, 5-phenyl tetrazole (245° C.),

triazines, such as, for example, trihydrazinotriazine (275° C.),

carboxylic acids, such as, for example, citric acid (150° C.), oxalic acid, glutaric acid,

dehydrating substances such as aluminum hydroxide (220° C.), magnesium hydroxide (350° C.), aluminum nitrate, sulfohydrazines, sodium (bi)carbonate, semicarbazides

Various propellants, especially azodicarbonamides, but also citric acid and the hydroxides of aluminum and magnesium, are less soluble in many of the matrix polymers that are used and therefore remain preferably on the domain particles. Optionally, the latter can also be microencapsulated.

Low-molecular substances are preferably used as coatings that partially decompose upon excitation and largely vaporize and thus form a separating layer in the region of or on the boundary surface of the domain particles. These coatings are absorbed on the domains or dissolved in them. Examples of such coatings are

waxes, such as, for example, paraffin waxes, amide waxes or ester waxes

oils, such as, for example, silicone oils, paraffin oils, fatty acid oils or fats.

If the propellant or coating is provided on a filler or it is coated with the latter, it is advantageous to modify the surface of the filler in order to obtain better dispersion or binding of the propellant or coating.

It is especially advantageous if excitation of the domains in the field takes place without contact, especially by electromagnetic waves. In this way, on the one hand, direct mechanical action on the film is ruled out; on the other hand, a corresponding excitation or activation unit can be easily arranged at almost any point in the production process. Thus, the activating units can be provided following a mixing extruder for the parent material upstream from a (pre)casting roller, upstream from a preheating zone and/or upstream from a stretching apparatus. Fundamentally, it is even possible to provide an activation unit downstream from the stretching apparatus when a propellant is used, and the propellant leads to gas formation such that a breakthrough of the film material or the matrix and thus the desired porosity are produced.

Fundamentally, there are various technical possibilities of contactless excitation, excitation being especially preferred by electromagnetic waves. One preferred alternative is the excitation of the domains by induction so that heating of the domains results. Here, it goes without saying that in this connection, only heating of the domains or in the region of the domains takes place, while the matrix is otherwise not heated or only slightly heated. Therefore, between the domains and the matrix, there are considerable temperature differences as a result of excitation. Moreover, it is pointed out that inductive excitation is defined as the film material being moved through a magnetic field, an electrical field or an electromagnetic field during or after production or during its subsequent processing or its use, and excitation is thus produced. At the same time, it is also defined as the application of a voltage even if this will not necessarily take place without contact. Inductive excitation also includes the domains having fillers that are embedded into the matrix. These fillers are ferromagnetic, ferrimagnetic, paramagnetic and/or superparamagnetic and/or electrically conductive, and piezoelectric in the case of application of an electrical voltage.

As magnetic fillers, especially materials or particles from the group consisting of iron, iron alloys, or iron-containing metal oxides, for example magnetite or manganese-iron oxide, especially gamma-Fe₂O₃ or Fe₃O₄ as well as mixtures thereof, are suitable. Nanoscale superparamagnetic particles, such as, for example, iron oxide-silicon dioxide composite particles, are also suitable. In conjunction with superparamagnetism, the blocking temperature below which paramagnetic behavior does not occur must be watched. The blocking temperature is preferably less than 250° K and especially preferably less than 305° K.

As metallic fillers, especially aluminum, zinc, copper, high-grade steel, bronze, silver or alloys of the aforementioned materials, especially copper-zinc alloys, are suitable. The fillers can be made in the form of powders or lamellae, flat or as so-called flakes.

As additional fillers that are suited for inductive excitation, polymers that are electrically conductive are suitable. They are undoped or doped polymers with continuously conjugated multiple bonds. In particular, the following are suitable here:

cis- or trans-polyacetylene (PA)

polyparaphenylene (PPP)

polythiophene,

polypyrrole,

poly(para-phenylene-vinylene) (PPV)

polyaniline (PANI)

The conductivities of the electrically conductive polymer fillers are in the range from 0.01 to 1,000,000 S/m, the undoped being rather in the range from 0.01 to 100 S/m. The polymer fillers are not all thermoplastic or have very high melting points, so that they retain in part their original particle form.

Furthermore, among the materials that are suitable for inductive excitation are carbon nanotubes and carbon fibers. Here, especially so-called single-wall or multi-wall carbon nanotubes (CNT), for example, SWNT 90% by weight or MWNT 10-20 nm from the CheapTubesInc. Company, or alternatively SWNT or MWT of less than 10 nm from the NTP Company, are of interest here. For the carbon fibers, for example, the product Torayca T010-3 from the Toray Company or cut Sigrefil C from the SGL Carbon Company is possible. Nickel-plated carbon fibers, for example the product Tenax-J MC HTA-12K A302 from the Toho Tenax Company, are also of interest.

In conjunction with inductive excitation, it is recommended that at least one coil or—at higher frequencies—space charge wave tubes, such as, for example, klystrons or magnetrons, be used as the activation unit. The activation unit should emit a frequency of between 30 Hz-300 GHz, preferably between 0.3-300 GHz, or between 10 kHz to 300 MHz, optionally connected to a direct current magnet between 0.015-4 tesla, preferably between 0.02 and 0.2 tesla. The duration of the magnetic excitation should be <300 s, preferably <60 s, and especially <10 s. Additional parameters in magnetic excitation are the particle size distribution, the Curie temperature, the permeability, the electrical resistance, and the thermal capacity. The parameters can be selectively set by one skilled in the art depending on the respective application.

Another possibility for activation comprises exciting the domains by radiation, especially by infrared radiation, the film material in this case being moved through a corresponding radiation field. In this connection, the domains then have fillers that comprise a radiation-absorbing material, especially an IR radiation-absorbing material, the matrix being made of a material that does not absorb radiation or that is less radiation-absorbent than the fillers. Fundamentally, it is also possible that the film has at least two incompatible plastics, of which one forms the domains and this plastic more strongly absorbing radiation with a given wavelength than the other plastic, which can even be fundamentally made so that no infrared radiation is absorbed. In addition, it can be provided that the film has at least two incompatible plastics, the domain plastic having at least one component that absorbs radiation with a given wavelength range. The aforementioned radiation-absorbing or correspondingly colored or pigmented plastics are so-called island polymers, while the other polymers are referred to as matrix polymers. Finally, in conjunction with radiation activation, it is also possible for the domains to be formed only by propellants, the propellant being radiation-absorbing and decomposing after activation with the formation of gas.

With respect to radiation activation, only infrared radiation is addressed below, it also being fundamentally possible to use radiation with other wavelengths for activation. The following text therefore relates fundamentally to other wavelength ranges.

In conjunction with infrared activation, corresponding IR emitters, for example, from the Heraeus Noblelight Company, can be used as activation units. Examples here are:

infralight NIR emitter, primarily for the entire short-wave range of roughly 0.6-3 μm

short wave emitter for the range of 0.8-4.5 μm

carbon emitters for the range of 1-6 μm.

The corresponding emitter spectra are known from the prior art.

The power of the IR activation units should be greater than 1 kW, preferably between 10 and 500 kW, and especially between 20 and 200 kW.

Fundamentally, the following values have been found to be suitable as excitation parameters:

The wavelength should be between 0.6-30 μm, depending on the application preferably also partial ranges thereof. The partial ranges are produced with prisms or preferably optical lattices or other filters.

The duration of excitation should be <300 s, preferably <30 s, and especially preferably <5 s.

The intensity should be between 0.5 kW/m²-1 MW/M², preferably between 2 kW/m²-300 W/m², the intensity at a shorter wavelength generally being higher than at a longer wavelength, therefore lower powers are required.

The degree of absorption of the absorbing components or domains should be >70%, preferably >80%, and especially preferably >90%. The degree of absorption of the transmitted component or of the matrix should be <30%, preferably <20%, especially preferably <10%. The different degrees of absorption between the domains and matrix ensure that selective excitation takes place.

As matrix polymers, optionally, with later (after)crosslinking, preferably thermoplastics, elastomers, and thermoplastic elastomers are suitable.

The thermoplastics can be especially polyolefins and their copolymers (PE, PP, COC, EVA, EMA, EEA, EBA, PS, SB, ABS, SAN, ASA, PVC, ionomers, etc.), polycarbonate, polyesters (PET, PBT, PTT), polyamides (PA 4, 6, 6.6, 11, 12, etc.), polyurethanes, polysiloxanes, poly(meth)acrylates, fluoropolymers (FEP, PFA, PTFE, PVDF), polyoxymethylenes, especially, however, PE, PP, PET and their copolymers as well as largely homogeneous mixtures thereof. The elastomers can be especially natural rubber, polybutadiene (BR), polyisoprene, styrene butadiene, fluororubber, butadiene-acrylonitrile copolymers (NBR), silicone rubber, as well as largely homogeneous mixtures thereof. The elastomers can be vulcanized or otherwise crosslinked. For thermoplastic elastomers, especially TPE-E, TPE-O, TPE-U, SEBS, EDPM, PEBA as well as largely homogenous mixtures thereof, are suitable.

As island polymers, fundamentally the aforementioned polymers are suitable. In this case, examples of noncompatible mixtures are the following: PP/PA, PP/PS, PP/PVS, PP/SAN, PP/EPDM, PBT/PP, PP/PC, PP/TPE-U, PE/PA, PE/PS and PE/ionomers.

The aforementioned matrix polymers are fundamentally also suitable in a film with magnetic or metallic domains that are excited by induction.

In addition to the aforementioned polymers and functional additives as well as domains, other additives for themselves or in combination in the film material can be contained:

softeners

light stabilizers

UV absorbers

pigments and dyes

antioxidants

metal deactivators that can acquire especially great importance here

lubricants, processing aids

fillers

propellants

reinforcing agents, such as fibers

compatibilizers

In one alternative embodiment, it is provided that the domains are excited by ultrasound and that the film material is routed through an acoustic field. Here, the acoustic spectrum of an acoustic means that produces the acoustic waves as an activation unit is set such that the material of the domains oscillates more strongly than the regions surrounding the domains. Accordingly, the material or the contents of the domains have a different oscillation behavior than the matrix material or the regions surrounding the domains. The frequency for ultrasonic excitation should be greater than 20 kHz, preferably between 20 and 100 kHz.

The pore size can be adjusted in a controlled manner in wide ranges by the process according to the invention by choosing corresponding parameters. The size extends from 1 to 1,000,000 nm, optionally even less, preferably from 10 to 100,000 nm. Thus, the pore size, for example, for battery separators/fuel cell membranes, is between 10 nm to 1000 nm, and for breathing membranes, especially for use in construction, between 100 nm to 10,000 nm.

The pore density can be essentially set by how much island material or how many domains are present and how they are distributed in the matrix. For fillers in this connection, the particle size and degree of filling as well as the dispersion quality are important. For polymers that form domains, especially the proportion of the total formulation, the viscosity and the surface tension compared to the matrix and the dispersion process are important, since here the island material is crushed and distributed in the matrix.

The characteristic quantities for the breathing membranes are the water vapor permeability for the pore density and the water-tightness for the upper pore size. The water-tightness (measured according to EN 1928:2001, but without support of the film) varies depending on the application, but for membranes for roof and facade structures, it is greater than 10 cm, preferably greater than 20 cm, and especially preferably greater than 1 m. The upper boundary value of water-tightness for thin membranes is, conversely, often determined by their maximum tearing force and not by the pore size and is therefore not cited here. Also, the water vapor permeability (measured according to DIN 1931 (23° C., 0 to 75% by weight relative humidity)) varies depending on the application, but for breathing membranes for roof and facade structures, it is 10 to 3,000 g/(m²*24 h), preferably 100 to 2,500 g/(m²*24 h), and especially preferably 200 to 2,000 g/(m²*24 h).

In order to make the pore size as uniform as possible, the size distribution of the domains should be relatively narrow. This means that the domains should have an at least essentially uniform size. This applies both to the magnetic and metallic particles, so that they have the same excitability as for the island domains in the incompatible blends and the propellant particles or propellant coatings. Fundamentally, the domains can have a maximum size roughly up to the thickness of the film. Their size depends on whether many small pores or those in which only a small gap opens around the domains are to form.

Examples of preferred particle sizes of certain feedstocks are:

Examples of magnetic particles: AdNano (nanoscale silicon dioxide particles with domains of modified iron oxides): <1,000 nm, preferably <500 nm, especially preferably between 2-100 nm. This ensures the best economic efficiency of inductive excitation. Other dimensions are also suitable, however, such as, for example, Magnif from the Minelco Company in the range of between 1-100 μm, preferably 10-60 μm.

Examples of metallic particles: for example, pigment powder from the Eckart Company with an average particle size of between 1-200 μm or Nano Fe/Ni powder from the NTP Company with a particle size of between 5-15 nm.

The ranges for infrared-excitable particles are between 1-100,000 nm, preferably between 10-10,000 nm, and especially preferably between 100-1,000 nm.

The ranges for island domains are between 1-1,000,000 nm, preferably between 100-100,000 nm, and especially preferably between 200-10,000 nm.

The ranges for the decomposing propellants must be smaller since the resulting gas provides for correspondingly larger pores. The ranges are between 1-5,000 nm, preferably between 10-1,000 nm, and especially preferably between 100-500 nm.

For the vaporizing coatings, much less gas is formed. This leads to a not so dramatic enlargement of the pores so that “normal particles” can be used. The ranges are between 1-100,000 nm, preferably between 10-10,000 nm, and especially preferably between 100-1,000 nm.

The film itself should have a thickness of less than 1 mm. Ranges of between 1 μm and 300 μm are preferred; ranges of between 10 μm and 100 μm are especially preferred.

As mentioned above, the number of domains or the degree of filling constitutes an important influencing factor for the pore density. For magnetic and metallic as well as electrically conductive fillers, the degree of filling should be between 0.1 and 70% by weight, preferably between 1 and 60% by weight, especially preferably between 2 and 50% by weight, and furthermore preferably between 5 to 30% by weight. When using propellants as such, the degree of filling is between 0.01 and 20% by weight, preferably between 0.2 and 10% by weight, and especially preferably between 0.5 and 5% by weight. For fillers with propellants or also only with an essentially vaporizing coating, the degree of filling is between 0.1 and 60% by weight, preferably between 0.5 and 40% by weight, and especially preferably between 1 and 20% by weight. For IR-absorbing fillers, the degree of filling is between 0.1 to 80% by weight, preferably 1 to 60% by weight, especially preferably 2 to 50% by weight, and furthermore preferably between 5 and 30% by weight. For island polymers, the degree of filling is between 0.5 and 40% by weight, preferably between 2 and 30% by weight, and especially preferably between 5 and 20% by weight.

It is pointed out that the range information above and also below encompasses all individual values and also intermediate ranges that are contained in the range boundaries even if the individual values and intermediate ranges are not mentioned in particular.

Embodiments of the invention are explained below with reference to the accompanying drawings.

### BRIEF DESCRIPTION OF THE DRAWINGS

FIG. 1 schematically depicts a production facility for producing porous films,

FIG. 2 is a schematic diagram showing part of a film before and after excitation and stretching,

FIG. 3 is a schematic diagram showing part of another film before and after excitation and stretching,

FIG. 4 is a schematic diagram showing part of another film before and after excitation,

FIG. 5 is a schematic diagram showing part of another film before and after excitation and stretching,

FIG. 6 is a schematic diagram showing part of another film before and after excitation and stretching,

FIG. 7 is a schematic diagram showing part of another film before and after excitation and further stretching,

FIG. 8 is a schematic diagram showing part of another film before and after excitation and stretching, and

FIG. 9 is a schematic diagram showing part of another film before and after excitation.

### DETAILED DESCRIPTION OF THE INVENTION

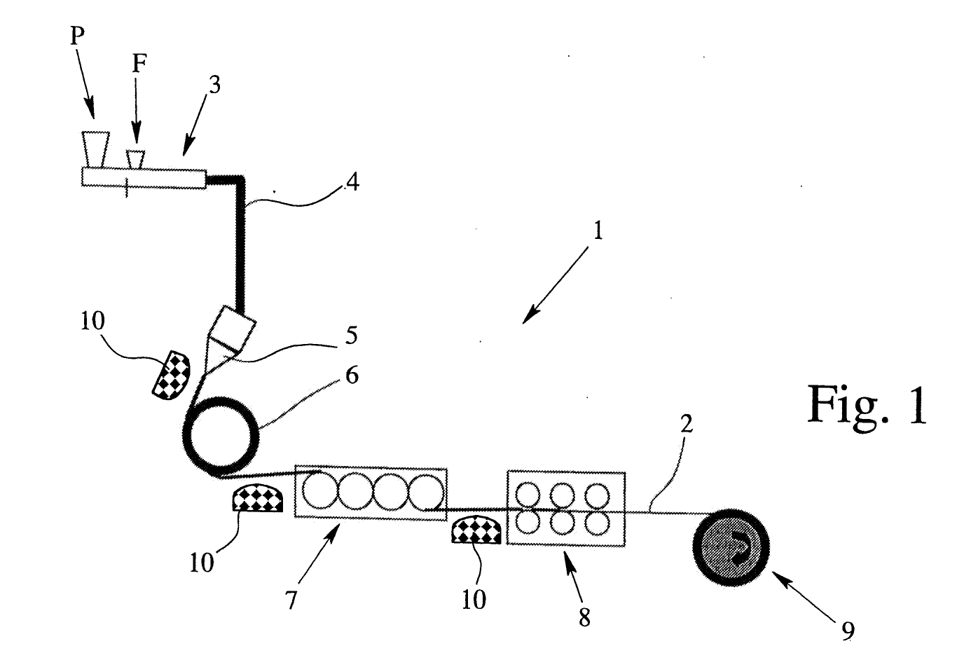

FIG. 1 shows a device 1 for producing cast porous films 2 that has an extruder 3 to which polymers P and filler F are supplied. The polymers P later form the matrix M, while the fillers F form the domains D. Mixing and homogenization of the supplied material take place in the extruder 3. This material is supplied to a broadband nozzle 5 by way of a supply line 4. The flat material originating from the nozzle 5 is conveyed by way of the casting roller 6. The casting roller 6, however, is used not only for removal, but here also for temperature control of the film 2. Moreover, it goes without saying that instead of a casting roller 6, there can also be a plurality of casting rollers or other conveyor means. Following the casting roller 6, the film 2 is supplied to the preheating means 7. The preheating means 7 can have a plurality of temperature-controlled rollers, or for example, a temperature-controlled chamber. Following the preheating means 7, the film is supplied to a stretching apparatus 8 that, here, is a monoaxial stretching apparatus 8, even though biaxial stretching is also possible. Following the stretching apparatus, the film is supplied to a take-up means 9.

In the illustrated device 1, there is an activation unit 10 between each of the nozzle 5 and the casting roller 6, the casting roller 6 and the preheating means 7, as well as between the preheating means 7 and the stretching apparatus 8. In this case, FIG. 1 illustrates only different alternative arrangements of the activation unit 10, it is fundamentally even possible to, likewise, provide an activation unit 10 between the stretching apparatus 8 and the take-up means 9. Even if it is fundamentally possible to have several activation units 10 for one device 1, it is generally sufficient if there is only one activation unit 10.

Moreover, it goes without saying that the invention is not limited to the generation of cast films. The invention relates in the same way to films by any type of production process. For example, blown films or those that have been obtained by conversion of dispersions or solutions into films can be produced. The film produced according to the process according to the invention can also be a coextruded film that is formed of several, optionally, different layers. Upstream stretching for increasing the basic strength is possible. The invention can also be used in other processes, however. Elastomer films can be produced, for example, on mixers and calenders using the process according to the invention. The porous film obtained in this way can be used by itself or in combination with other layers. They are, for example, reinforcing layers or protective layers. In this case, the film is further processed according to processes that are known in the art, such as coating, lamination or bonding. The film can also be connected to at least one other layer before activation, for example, by extrusion coating, lining, lamination or bonding. Excitation then takes place on the composite itself, the film part or the film parts of the composite being heated in the same manner as described above.

Moreover, this invention relates not only to the film produced according to the process according to the invention as such, but especially also to the film material produced from the film and the parts produced therefrom.

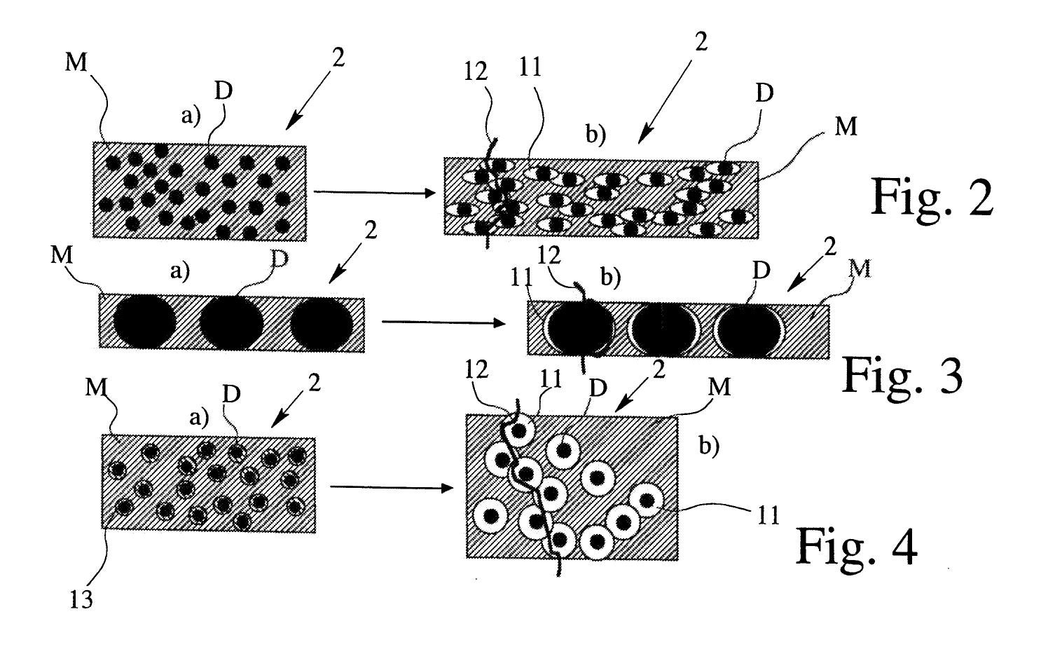

FIGS. 2 to 9 show different partial principles of this invention to which reference is made below. Here, the table below summarizes the principles or partial principles as follows:

| Principle/Excitation | | Partial Principle |
|---|---|---|
| Inductive Excitation | 1.1 | Magnetic or Metallic Particles and |
| | | Stretching |
| | 1.2 | Magnetic or Metallic Particles and |
| | | Propellants |
| | 1.3 | Magnetic or Metallic Particles and |
| | | Vaporizing Coating |
| | 1.4 | Special Cases: Conductive Polymers, |
| | | Carbon Nanotubes, Carbon Fibers, |
| | | as well as Piezoelectric Materials |
| Radiation, Especially | 2.1 | Absorbing Filler and Transparent |
| Infrared Excitation | | Matrix |
| or Ultrasonic | 2.2 | Mixing of Incompatible Polymers, of |
| Excitation | | which one is IR-Absorbent |
| | 2.3 | Mixing of Incompatible Polymers, of |
| | | which one is Colored or Pigmented |
| | | to be Absorbent |
| | 2.4 | Absorbing Propellant and Transparent |
| | | Matrix |

It is pointed out that only especially preferred principles of excitation by electromagnetic waves are given in the table above.

FIGS. 2 and 3 show the partial principle 1.1. Here, FIG. 2a schematically shows a part of a film 2 before excitation and stretching. The film 2 has a matrix M made of plastic and a host of small domains D. The domains D are magnetic particles whose thickness is smaller than the thickness of the film 2. Conversely, FIG. 3a shows a film 2 in which the domains D have a thickness or a diameter that corresponds at least essentially to the thickness or the diameter of the film 2.

FIGS. 2b and 3b show the state of the film 2 after excitation and stretching. In particular, FIG. 2b shows that the thickness of the film 2 has decreased after stretching. By stretching, cavities 11 have formed on the boundary surfaces of the domains D in the direction of stretching. Correspondingly, great stretching yields detachment of the film 2 in the region of the cavities 11 from the domains D. Here, pores 12 form, of which one is shown schematically. The pores 12 arise by the connection of a series of individual cavities 12 of the domains D.

While relatively great stretching in the embodiment as shown in FIG. 2 has been undertaken, in the embodiment as shown in FIG. 3, elongation or stretching that is only slight in contrast has been undertaken. In this case, pores 12 arise on the boundary surfaces of the domains D.

Tests have been done in conjunction with the inductive excitation of magnetic domains D and subsequent stretching. In this case, on a twin-screw extruder, 65% by weight of magnetite with an average particle size of 10 μm was dispersed in 35% by weight of polypropylene copolymer, discharged, cooled and granulated. A mixture of 37% by weight of this granulate, 61% by weight of polypropylene copolymer, and 2% by weight of stabilizer concentrate was cast into a film of 50 g/m² using a single screw extruder. The film was preheated to 125° C. subsequently at a speed of 15 m/min by means of several heated rollers, and the magnetic particles were selectively heated by means of induction at 80 kHz and with a power of 125 kW. Then, monoaxial stretching by a factor of 1.5 into a film of roughly 35 g/m² was performed. After cooling, water-tightness of a 1.3 m water column and a water vapor permeability of 220 g/(m²*24 h) were measured.

FIG. 4 shows the partial principle 1.2. FIG. 4a shows part of a film 2 that corresponds essentially to the embodiment according to FIG. 2a, the domains D, however, having a coating 13 of a propellant. After excitation, the propellant decomposes, and comparatively large cavities 11 are produced around the individual domains D. In this case, a porosity or pores can already form by individual cavities 11 passing into one another, and pores 12 extending from the top to the bottom are produced. The resulting gas accordingly inflates the film around the domains so that a greater thickness of the film 2 arises in 4b compared to 4a.

The film 2 that is shown in extract in FIG. 4a can then still be stretched, which is not shown, so that the porosity increases further. In this case, the thickness of the film 2 then decreases again.

A test has also been run in conjunction with inductive excitation of magnetic particles that are coated with the propellant. Here,100 g of azodicarbonamide was dissolved in boiling dimethyl formamide (DMF). In the solution, 1,000 g of magnetite with an average particle size of 0.5 μm was dispersed, the DMF cooled with constant stirring, largely distilled off in a vacuum, and the cooled mixture was filtered. The powdery residue was magnetic particles jacketed with propellant. The latter were dispersed on a twin-screw extruder with 20 times a polypropylene random copolymer and cast into a primary film of 85 g/m². The film was subsequently preheated at a speed of 15 m/min by means of several heated rollers to 135° C., the magnetic particles or domains selectively heated by means of induction at 80 kHz and with a power of 125 kW, and the film was biaxially stretched by a factor of 1.1 in both directions. In doing so, the azodicarbonamide decomposed so that an open-cell film was formed. After cooling, water-tightness of a 0.6 m water column and a water vapor permeability of 358 g/(m²*24 h) were measured.

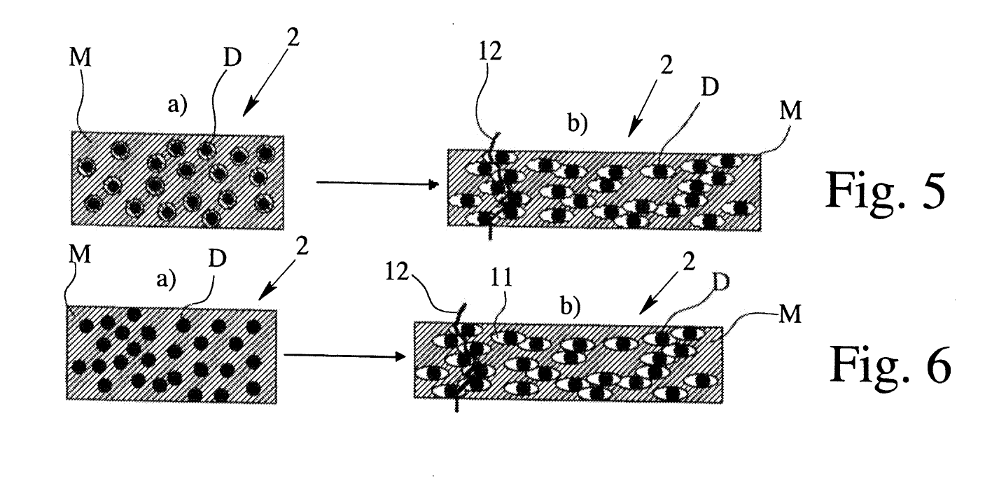

FIG. 5 shows the partial principle of use of magnetic domains D that are provided with a vaporizing coating 13 or a coating (partial principle 1.3). After excitation and stretching, a film 2 that is very similar to the one according to FIG. 2b is formed.

In conjunction with a test based on this principle, 1,000 g of silicon dioxide coated aluminum pigments (STAPA IL Hydrolan 701 from the Eckart Company with D50 of 16 μm) was washed in gasoline and filtered. The residue was dispersed in liquid stearic acid. After filtering, analogously to the embodiment described in conjunction with FIG. 2, low-density polyethylene was incorporated so that 40% by weight of coated pigments was contained in the plastic. Subsequent extrusion by way of a blown film system yielded a primary film of 30 g/m². After cutting and laying the tubing flat, at a speed of 45 m/min by means of several heated rollers, the film was preheated to 85°, and the magnetic particles were selectively heated by means of induction at 3 GHz and with a power of 92 kW, by which the stearic acid in part vaporized. Then, monoaxial stretching by a factor of 2 into a film of roughly 15 g/m² was performed. After cooling, water-tightness of a 0.2 m water column and a water vapor permeability of 1,050 g/(m²*24 h) was measured.

FIG. 6 shows the principle of infrared activation when using an absorbing filler as domains D in a transparent matrix M according to partial principle 2.1. In terms of the schematic view, this corresponds to FIG. 2. In a test in this respect, 35% by weight of chalk (Omyafilm 704 from the Omya Company with a D50 of 2 μm) and 65% by weight of polybutylene terephthalate (PBT, Ulradur 4500 from the BASF Company) were mixed in a double-screw extruder, and the PBT was melted. After extrusion into a cast film of 55 g/m², the latter was irradiated with an IR emitter and upstream filter, so that the chalk was selectively heated. In this connection, a separating layer formed around the chalk particles. Monoaxial stretching by a factor of 1.2 yielded a breathing film with a weight per unit of area of 46 g/m² with a water column of >1.5 m and a water vapor permeability of 175 g/(m²*24 h). The film was then discontinuously cement-coated with a hot melt on both sides with polyester spun bond fabric of 55 g/m² each. The water column remained unchanged; of the water vapor permeability, 160 g/(m²*24 h) remained. It was possible to use this composite as a roof undersheet and as a facade sheet.

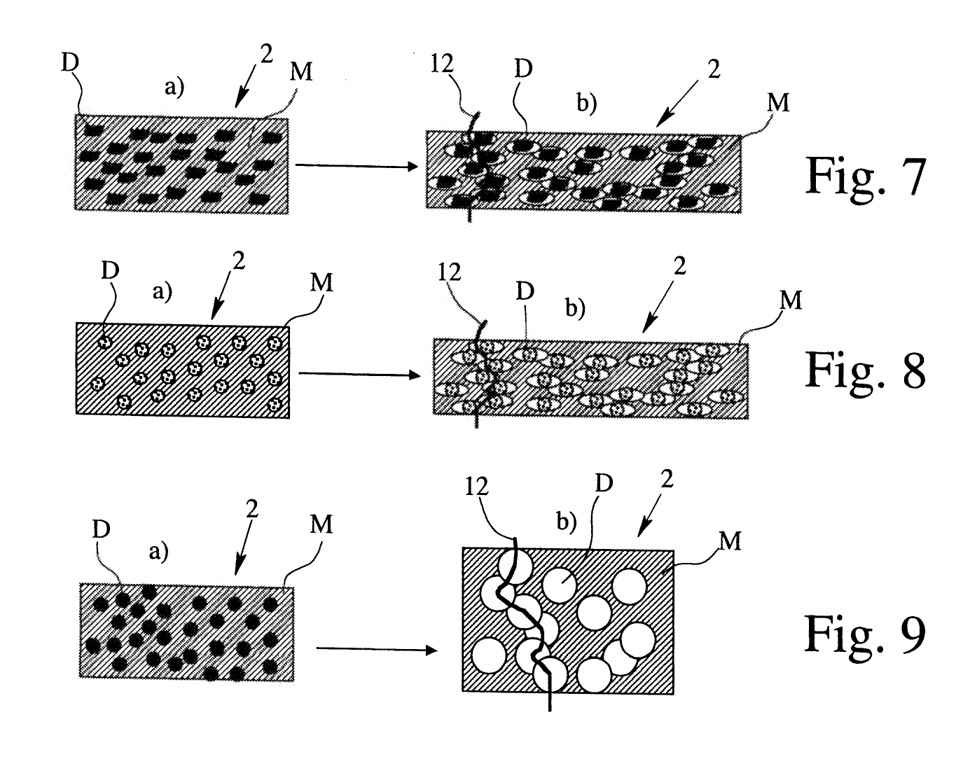

FIG. 7 schematically shows the partial principle 2.2. The film 2 has a mixture of incompatible polymers, the IR-radiation-absorbing polymers as island polymers forming the domains D. The other polymers form the matrix M. After IR activation and subsequent stretching, conditions as in FIG. 2b arise.

FIG. 8 shows the partial principle 2.3. The domains D are formed here by polymers that are colored or pigmented to be absorbent. The other polymers form the matrix M. In a test conducted in this regard, a compound of 30.5% by weight of soot in 95% by weight of polystyrene (Plasblak PS 0469 from the Cabot Company) was used. In a further step, 16% by weight of the pretreated polystyrene was compounded with 82% by weight of polypropylene on a twin-screw extruder and cast into a film of 40 g/m². In an examination, it was shown that the average size of the elongated polystyrene islands is roughly 5 μm, and the soot remained almost completely in the polystyrene. After preheating to 115° C., selective heating of the soot-containing polystyrene islands is done with NIR emitters, the wavelength of the filtered radiation being roughly 0.8-2.1 μm. The power was 4 kW/m2. Then, stretching by a factor of 1.25 was performed. After cooling, water-tightness of a 1.1 m water column and a water vapor permeability of 315 g/(m²*24 h) were measured.

FIG. 9 shows principle 2.4 in which the domains D are formed by IR-absorbing propellant, while the matrix M is largely IR-transparent. After excitation, the domains D constitute cavities 11 that can communicate with one another and thus form pores 12. In a test in this respect, 1.5% by weight of azodicarbonamide was compounded in 98.5% by weight of LDPE and discharged from a wide slit nozzle, the temperature of the mass not having exceeded 190° C. The melt was cooled on a temperature-controlled pre-casting roller to 110° C. When subsequently routed past an IR emitter, the azodicarbonamide was ignited, yielding a breathing film. After cooling, water-tightness of a 0.25 m water column and a water vapor permeability of 630 g/(m²*24 h) were measured.

In a similar test, instead of pure azodicarbonamide, a nanoscale silicon dioxide coated with azodicarbonamide was used. When the propellant coating was ignited, very small pores of <900 nm formed.

1-20. (canceled)

21. Process for producing porous films, the film having a matrix made of plastic and discrete domains in the matrix, comprising the steps of:
exposing the film to a field for selective excitation of the domains, the domains being selectively heated relative to the remainder of the matrix by the selective excitation, and
producing pores in the regions at which the domains are or were located.

22. Process according to claim 21, further comprising the step of uniformly distributing the domains in the film.

23. Process according to claim 21, wherein the pores are produced in the regions at which the domains are located by stretching the film during or after said excitation of the domains.

24. Process according to claim 21, wherein in or on the domains, there is a pore former in the form of at least one of a propellant, a heat decomposable coating and a heat vaporizable coating.

25. Process according to claim 21, wherein excitation is produced in a noncontact manner.

26. Process according to claim 21, wherein said excitation of the domains is produced by induction and wherein the film is moved through at least one of a magnetic field, an electrical field and an electromagnetic field.

27. Process according to claim 21, wherein said excitation of the domains is produced by infrared radiation, and wherein the film is moved through an infrared radiation field.

28. Process according to claim 21, wherein said excitation of the domains is produced by a light wave spectrum radiation means that produces radiation which is absorbed by the domains while the radiation is absorbed by regions surrounding the domains to a lesser degree than the domains or not at all.

29. Process according to claim 21, wherein said excitation of the domains is produced by ultrasound and wherein the film is routed through an acoustic field.

30. Process according to claim 29, wherein the acoustic spectrum of the acoustic field produces acoustic waves that oscillate the domains more strongly than regions surrounding the domains.

31. Process according to claim 21, wherein at least one of the size and number of pores in the film material is controlled by at least one of the type and number of domains, the temperature of the film material, the timing, duration and intensity of excitation, a degree of stretching of the film and an amount of propellant use with the domains.

32. A porous film material, comprising:
a plastic matrix,
discrete domains in the matrix, and
pores in the region of the domains that have been produced from the domains by selective excitation heating thereof in a field.

33. Porous film material according to claim 32, wherein the pores have been produced by a decomposed or vaporized propellant or coating on the domains.

34. The porous film material according to claim 32, wherein the domains have fillers that are one of ferromagnetic, ferrimagnetic, paramagnetic, superparamagnetic, electrically conductive, and piezoelectric.

35. The porous film material according to claim 32, wherein the domains have fillers of an infrared radiation-absorbing material that is surrounded a material that absorbs less IR radiation than the fillers.

36. The porous film material according to claim 35, wherein the domains are formed of at least two incompatible plastics, one plastic absorbing infrared radiation of a given wavelength range to a greater extend than the other plastic.

37. The porous film material according to claim 35, wherein the domains are formed of at least two incompatible plastics, one of the plastics having at least one component that absorbs infrared radiation of a given wavelength range.

38. The porous film material according to claim 32, wherein the domains are formed of a material that has a different oscillation behavior than material surrounding the domains.
